(19) United States
(12) Patent Application Publication
(10) Pub. No.: US 2019/0089880 A1
(43) Pub. Date: Mar. 21, 2019

(54) IMAGE CAPTURING DEVICE

(71) Applicant: SHARP KABUSHIKI KAISHA, Sakai City (JP)

(72) Inventor: TAKEHIRO MURAO, Sakai City (JP)

(21) Appl. No.: 16/131,717

(22) Filed: Sep. 14, 2018

(30) Foreign Application Priority Data
Sep. 15, 2017 (JP) 2017-178144

(51) Int. Cl. H04N 5/225; G02F 1/1335; G02F 1/1343; G02F 1/1368; G02F 1/1339; G03B 11/00; G02B 5/20; H01L 27/32; B60R 11/04; B60R 11/00

(52) U.S. Cl. CPC H04N 5/2257; G02F 1/133528; G02F 1/13439; G02F 1/1368; G02F 1/133514; G02F 1/133512; B60R 2011/0003; G03B 11/00; G02B 5/208; H01L 27/3234; B60R 11/04; B60R 11/00; G02F 2001/133531; G02F 1/1339

(57) ABSTRACT

To provide an image capturing device including a display which image capturing device has an appearance influenced less by the display and can be produced at a lower cost, an image capturing device includes (i) an image forming layer containing a first and second polarizing plates, (ii) a camera and IR light sources placed on the back-surface side of the image forming layer, and (iii) a facing portion facing the camera and the IR light sources from which facing portion an electronic circuit and color material have been removed as appropriate.

### TECHNICAL FIELD

The present invention relates to an image capturing device.

### BACKGROUND ART

The automobile industry is seeing a trend for an on-vehicle display to become larger and another trend for an automobile to be equipped with a driver monitoring system (DMS) for monitoring the driver. An automobile, however, has only a limited space for a DMS. Since a DMS requires a camera to capture an image of the driver, there is a need to place a large-sized display and a camera in a limited space.

A known example of such a display equipped with a camera is a DMS display device that combines a normal liquid crystal panel, a camera, and a light source of infrared light (see, for example, Patent Literature 1). This display device includes (i) a liquid crystal panel having a partial, infrared light transmitting region, (ii) a backlight, and (iii) a camera placed behind the infrared light transmitting region.

The backlight includes (i) a light guide plate and (ii) white LEDs and IR LEDs alternately arranged along a side of the light guide plate. The infrared light transmitting region is formed by partially removing a pattern on the light guide plate or forming a hole so as not to prevent infrared light from traveling in a straight line.

The display device further includes an infrared light filter in front of the camera in the infrared light transmitting region which infrared light filter serves to (i) cut off visible light and (ii) render the color of red less visible. As described above, the display device utilizes the property of red (R) pixels allowing infrared light to pass therethrough and includes a camera hidden behind the display for an improved appearance.

### CITATION LIST

### Patent Literature

[Patent Literature 1]

Japanese Patent Application Publication, Tokukai, No. 2014-031140 (Publication Date: Feb. 20, 2014)

### SUMMARY OF INVENTION

### Technical Problem

Conventional techniques such as the above unfortunately involve the following issue: In a case where a camera is placed in the vicinity of an image display region of the display, the display has a less attractive appearance or may require a higher cost.

A display normally includes a frame (typically black) around the image display region to define the image display region. In a case where, for instance, the camera is to be hidden by a frame on the display-surface side of the display, that frame will need to be wider for the camera to be hidden. Further, since infrared light needs to travel forward from the camera, the frame will have a portion in front of the camera which portion looks different from its surrounding portion.

It is usually more expensive to produce, for example, a display having a shape different from normal in correspondence with the shape of the camera than to produce a display having a normal shape such as a rectangle and a trapezoid. Further, since the portion in front of the camera will look different from the display in this case as well, the display will have a less attractive appearance.

An aspect of the present invention has an object of providing an image capturing device including a display which image capturing device has an appearance influenced less by the display and can be produced at a lower cost.

### Solution to Problem

In order to attain the above object, an image capturing device in accordance with an aspect of the present invention includes: an image forming layer for forming an image in an image display region; a polarizing plate provided inside the image forming layer or on a display-surface side of the image forming layer; a camera provided on a back-surface side of the image forming layer and facing the display-surface side of the image forming layer; and a light source provided on the back-surface side of the image forming layer and facing the display-surface side of the image forming layer so as to emit infrared light toward the display-surface side, the image forming layer having a facing portion facing the camera and the light source from which facing portion an electronic circuit, a colored portion, and a black matrix have been removed partially or entirely.

### Advantageous Effects of Invention

An aspect of the present invention provides an image capturing device including a display which image capturing device has an appearance influenced less by the display and can be produced at a lower cost.

### BRIEF DESCRIPTION OF DRAWINGS

(a) of FIG. 1 is a schematic front view of an image capturing device in accordance with Embodiment 1 of the present invention. (b) of FIG. 1 is a schematic cross-sectional view of the image capturing device taken along line B-B in (a) of FIG. 1.

FIG. 2 is a development view of the image capturing device, the view schematically showing how members of the image capturing device are arranged.

(a) of FIG. 3 is a diagram schematically illustrating the respective structures of a thin film transistor (TFT) substrate and color filter substrate included in the image capturing device. (b) of FIG. 3 is a diagram schematically illustrating an enlargement of the portion indicated with “B” in (a) of FIG. 3.

FIG. 4 is a development view of an image capturing device in accordance with Embodiment 2 of the present invention, the view schematically showing how members of the image capturing device are arranged.

(a) of FIG. 5 is a diagram schematically illustrating an example of wiring on a TFT substrate included in the image capturing device. (b) of FIG. 5 is a diagram schematically illustrating another example of wiring on the TFT substrate included in the image capturing device.

FIG. 6 is a development view of an image capturing device in accordance with Embodiment 3 of the present invention, the view schematically showing how members of the image capturing device are arranged.

(a) of FIG. 7 is a diagram schematically illustrating an example of wiring on a TFT substrate included in the image capturing device. (b) of FIG. 7 is a diagram schematically illustrating another example of wiring on the TFT substrate included in the image capturing device.

(a) of FIG. 8 is a diagram schematically illustrating an example of how members of the image capturing device in accordance with Embodiment 4 of the present invention are stacked. (b) of FIG. 8 is a cross-sectional diagram schematically illustrating an example of how members of a switch liquid crystal layer for the image capturing device are stacked.

FIG. 9 shows flow diagrams schematically illustrating an example method for forming a pattern of an indium tin oxide (ITO) electrode on a SEG substrate included in the switch liquid crystal layer.

FIG. 10 is a diagram schematically illustrating another example of how members of the image capturing device are stacked.

(a) of FIG. 11 is a schematic front view of the image capturing device in accordance with Embodiment 5 of the present invention. (b) of FIG. 11 is a development view of the image capturing device, the view schematically showing how members of the image capturing device are arranged.

### DESCRIPTION OF EMBODIMENTS

### Embodiment 1

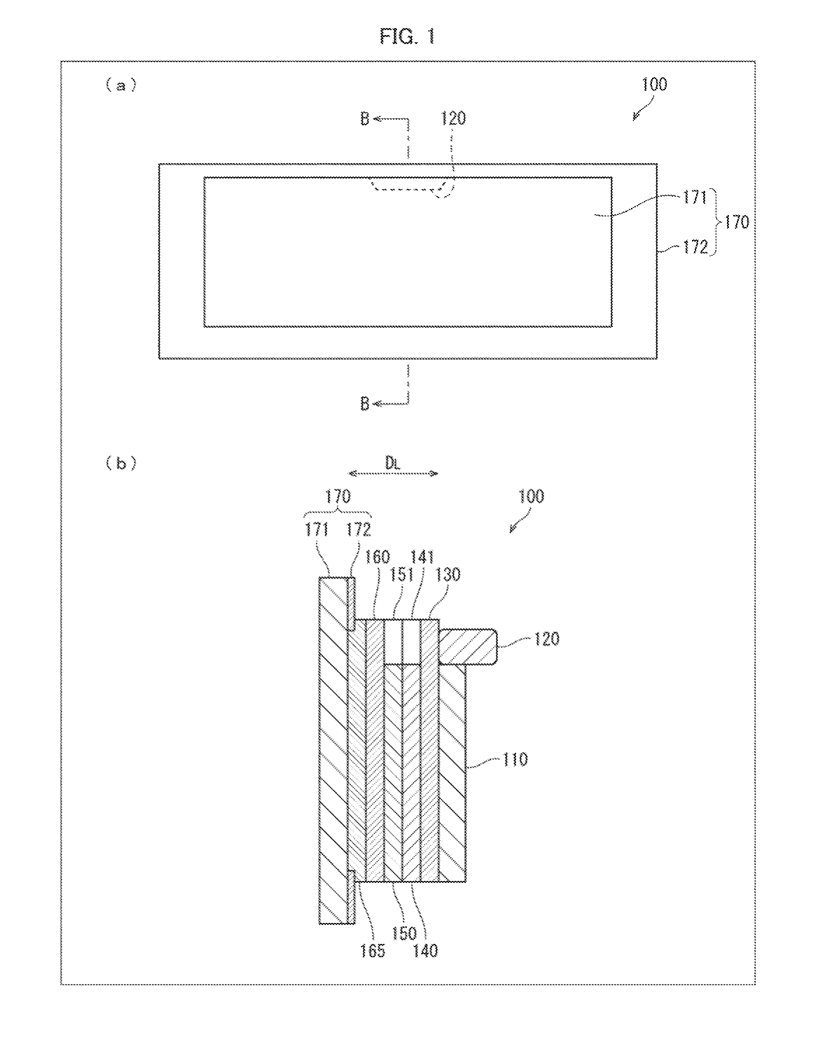

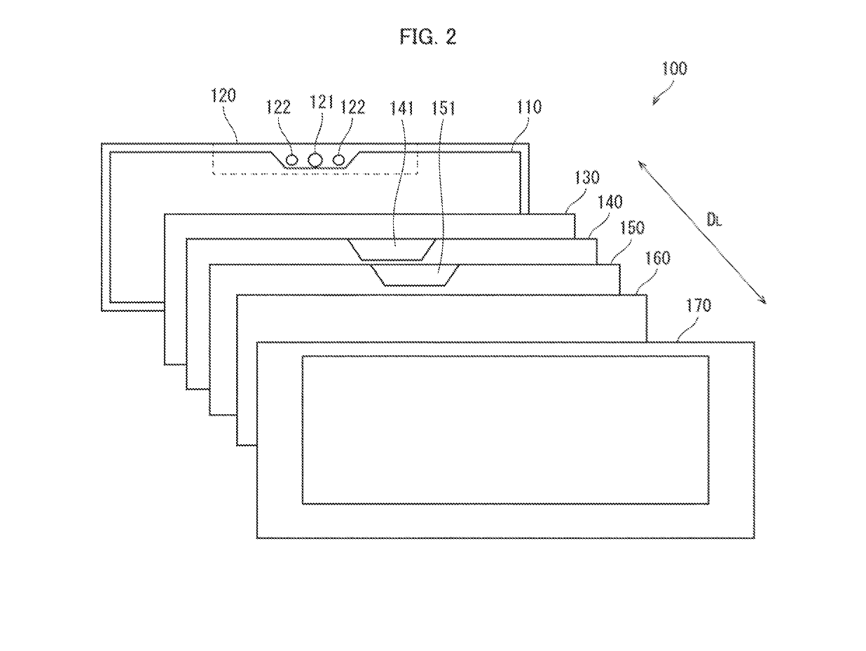

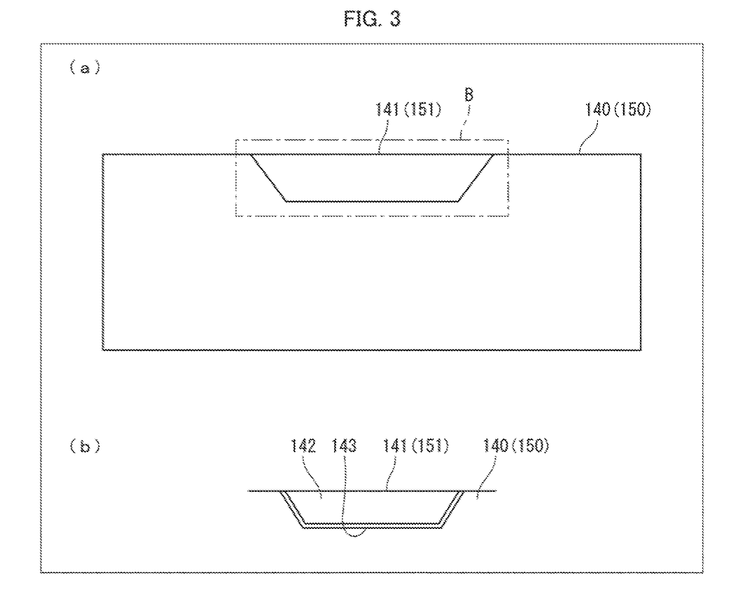

The following description will discuss embodiments of the present invention in detail. (a) of FIG. 1 is a front view of an image capturing device in accordance with Embodiment 1 of the present invention, the view schematically showing the configuration of the image capturing device. (b) of FIG. 1 is a schematic cross-sectional view of the image capturing device taken along line B-B in (a) of FIG. 1. FIG. 2 is a development view of the image capturing device, the view schematically showing how members of the image capturing device are arranged. The image capturing device includes a camera unit and a liquid crystal display device, the liquid crystal display device being, for example, a vertical alignment (VA) display device.

The image capturing device 100, as illustrated in (a) and (b) of FIG. 1 and FIG. 2, includes a backlight 110, a camera unit 120, a first polarizing plate 130, a thin film transistor (TFT) substrate 140, a color filter substrate 150, a second polarizing plate 160, and a cover glass 170. The members other than the backlight 110 each have a rectangular planar shape. The TFT substrate 140 and the color filter substrate 150 sandwich a liquid crystal layer. The cover glass 170 is attached to the second polarizing plate 160 with use of an optical clear adhesive (OCA) sheet 165.

The backlight 110 is a light source for a liquid crystal panel. The backlight 110 has a substantially rectangular planar shape; specifically, the backlight 110 is in the shape of a substantial rectangle having a trapezoidal cutout at a central portion of a long side of the substantial rectangle. The trapezoid has (i) a long side shared by the long side of the substantial rectangle, (ii) a short side parallel to the long side and closer to the center of the substantial rectangle, and (iii) two oblique sides one of which connects one end of the long side with one end of the short side and the other of which connects the other end of the long side and the other end of the short side. The backlight 110 is configured similarly to publicly known backlights except for the above cutout.

The camera unit 120 is positioned at the cutout of the backlight 110. The camera unit 120, for example, has an elongated rectangular planar shape, and includes a camera 121 and IR light sources 122. The camera 121 is positioned at a central portion of the camera unit 120 in the longitudinal direction of the planar shape. The IR light sources 122 are positioned respectively on opposite sides of the camera 121.

The camera 121 is an image sensing element such as a CCD image sensor or a CMOS image sensor. The camera 121 is positioned at a central portion of the cutout and oriented to face the display-surface side of the cover glass 170. The IR light sources 122 are each a device configured to emit infrared light such as infrared light having a wavelength of not less than 940 nm. The IR light sources 122 each serve to irradiate an object for the camera 121 with infrared light. The IR light sources 122 are positioned at the cutout and on opposite sides of the camera 121, and are oriented to face in the same direction as the camera 121.

The first polarizing plate 130 and the second polarizing plate 160 can each be selected as appropriate from among polarizing plates that are publicly known to be usable for liquid crystal display devices. The first polarizing plate 130 and the second polarizing plate 160 do not substantially polarize infrared light, and each include, for example, a polarizer prepared by stretching polyvinyl alcohol (PVA) stained with use of iodine or a dichroic pigment. The second polarizing plate 160 is oriented in such a manner as to meet a crossed Nicol relation with the first polarizing plate 130 (that is, the first polarizing plate 130 and the second polarizing plate 160 are oriented in such a manner that their respective polarization directions are orthogonal to each other).

The TFT substrate 140 is, as illustrated in (a) of FIG. 3, identical in configuration to TFT substrates publicly known to be usable for liquid crystal display devices except that the TFT substrate 140 includes a facing portion 141. The TFT substrate 140 includes, for example, (i) a glass substrate, (ii) a plurality of TFTs present on a surface of the glass substrate in such a pattern as to correspond to pixels, and (iii) a plurality of display electrodes connected respectively to the plurality of TFTs. The display electrodes are transparent, and are made of, for example, ITO (hereinafter the display electrodes are referred to also as “first transparent electrodes”).

The facing portion 141 includes that portion of the TFT substrate 140 which coincides with the cutout of the backlight 110 in the direction (stacking direction) in which the individual members of the image capturing device 100 are stacked (that is, the direction indicated with the arrow D_{L} in (b) of FIG. 1 and FIG. 2). The facing portion 141 is in the shape of, for example, a trapezoid as with the cutout of the backlight 110.

Any electronic circuit corresponding to the facing portion 141 of the TFT substrate 140 has been removed from the glass substrate. Such an electronic circuit includes, for example, a switching element and wiring. The electronic circuit may be removed from the glass substrate with use of a publicly known technique. The electronic circuit may be substantially removed as follows, for example: When switching elements and wiring are to be produced by normal photolithography, a mask is used for exposure so that no pattern for switching elements or wiring will be present in an area corresponding to the facing portion.

The color filter substrate 150 is, similarly to the TFT substrate 140, identical in configuration to color filter substrates publicly known to be usable for liquid crystal display devices except that the color filter substrate 150 includes a facing portion 151 (see (a) of FIG. 3). The color filter substrate 150 includes, for example, (i) a glass substrate, (ii) a color filter section on a surface of the glass substrate, and (iii) a transparent electrode on the color filter section. The color filter section includes (i) for each pixel, three colored portions having respective colors of red (R), green (G), and blue (B) and corresponding to respective sub-pixels and (ii) a black matrix surrounding each sub-pixel. The transparent electrode serves as a common electrode, and is made of, for example, ITO (hereinafter the common electrode is referred to also as “second transparent electrode”).

The facing portion 151, similarly to the facing portion 141, includes that portion of the color filter substrate 150 which coincides with the cutout of the backlight 110 in the stacking direction. The facing portion 151 is in the shape of, for example, a trapezoid as with the cutout of the backlight 110.

Any color material corresponding to the facing portion 151 of the color filter substrate 150 has been removed from the glass substrate. Examples of the color material include colored portions of the color filter section and a black matrix. The color material may be removed from the glass substrate with use of a publicly known technique. The color material may be substantially removed as follows, for example: When the color filter section is to be produced by normal photolithography, a mask is used for exposure so that no pattern for the color filter section will be present in an area corresponding to the facing portion.

As illustrated in (b) of FIG. 3, in the image capturing device 100, a space on the side of the above liquid crystal layer of the facing portions 141 or 151 is filled with a light-transmitting medium 142, for example, the liquid crystal composition of which the above liquid crystal layer is made, to ensure light transmissivity and reduce light refraction. The facing portions 141 and 151, each of which is in the shape of a trapezoid as described above, each have three sides other than the long side (that is, two oblique sides and a short side therebetween) along which three sides a black matrix 143 is present. The facing portions 141 and 151 are thus each bordered with a black matrix 143.

The cover glass 170 includes a glass plate 171 and a frame 172. The glass plate 171 has a rectangular planar shape larger than the backlight 110, the first polarizing plate 130, the TFT substrate 140, the color filter substrate 150, and the second polarizing plate 160, which are disposed behind the glass plate 171.

The frame 172 includes wide, straight-line portions extending on the back surface of the glass plate 171 along side edges and end edges of the glass plate 171. The frame 172 defines a rectangular opening inside which opening is smaller than the planar shape of the second polarizing plate 160 and which opening corresponds to an image display region. The image display region also has a facing portion, that is, a portion that coincides with the camera 121 and the IR light sources 122 in the stacking direction. The members of the image capturing device 100 that are other than the camera unit 120 correspond to an image forming layer for forming an image in the image display region.

The image display region displays a desired image with use of a liquid crystal. The above facing portion, which is inside the image display region, is a trapezoidal portion that slightly protrudes from the frame 172 into the image display region at a central portion of a long side of the image display region. The facing portion thus causes hardly any substantial influence on the image display.

The camera unit 120 is positioned at the cutout of the backlight 110. The image capturing device 100 includes, between the backlight 110 and the cover glass 170, two polarizing plates (namely, the first polarizing plate 130 and the second polarizing plate 160) for liquid crystal display that are oriented in such a manner as to meet a crossed Nicol relation. These polarizing plates cut off visible light. This prevents the camera unit 120, which is inside the image display region, from being easily visible from the display-surface side of the image capturing device 100. The camera unit 120 thus does not substantially impair the appearance of the liquid crystal display panel, with the result of the image capturing device 100 having an attractive appearance.

The image capturing device 100 may include first and second polarizing plates 130 and 160 each having a rectangular planar shape and a cover glass 170 having a rectangular planar shape. The first and second polarizing plates 130 and 160 and the cover glass 170 may thus be rectangular members for displaying images of a typical liquid crystal display device. Producing the image capturing device 100 is thus less expensive than producing an image capturing device including a liquid crystal display device that requires members each having a peculiar shape for a camera to be disposed.

When the image capturing device 100 is operated for image capturing, the IR light sources 122 emit infrared light (for example, infrared light having a wavelength in the vicinity of 940 nm) onto an object present on the display-surface side so that an image of the object is captured by the camera 121. Infrared light has a sufficiently high transmittance with respect to the first and second polarizing plates 130 and 160, which are oriented in such a manner as to meet a crossed Nicol relation. Infrared light having a wavelength of 940 nm or more, for example, has a transmittance of 85% or more with respect to the first and second polarizing plates 130 and 160 and the cover glass 170. This allows the camera 121 to capture a sufficiently vivid image.

Infrared light tends to be blocked or refracted by an electronic circuit including a switching element and wiring and be scattered as a result. Infrared light may also be absorbed by a color material such as a colored portion of a color filter or a black matrix. However, such an electronic circuit and color material have been substantially removed from the facing portion of the image display region. Further, the respective facing portions 141 and 151 of the TFT substrate 140 and the color filter substrate 150 are filled with a liquid crystal composition. This prevents the refractive index of infrared light from changing at the facing portions. This allows infrared light to have a high transmittance at the facing portions. The image capturing device 100 is thus effective, as the camera 121 is capable of capturing a vivid image.

### Embodiment 2

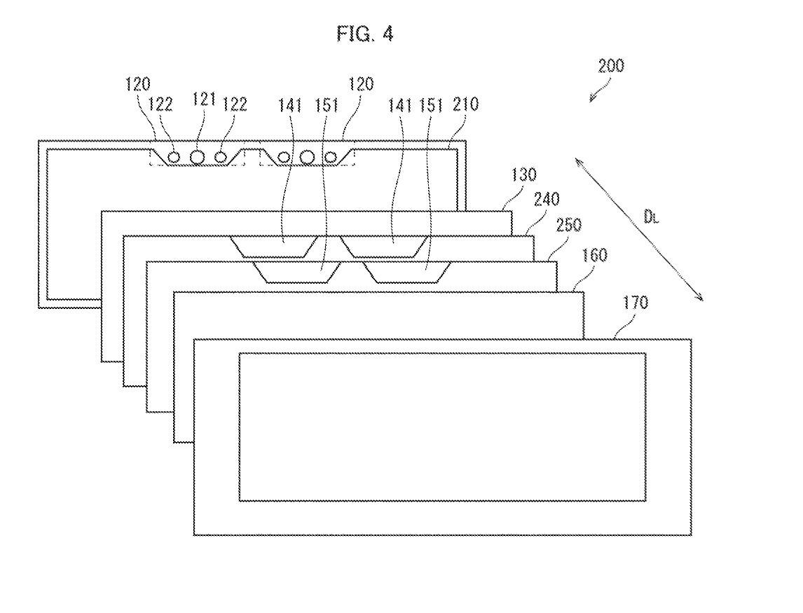

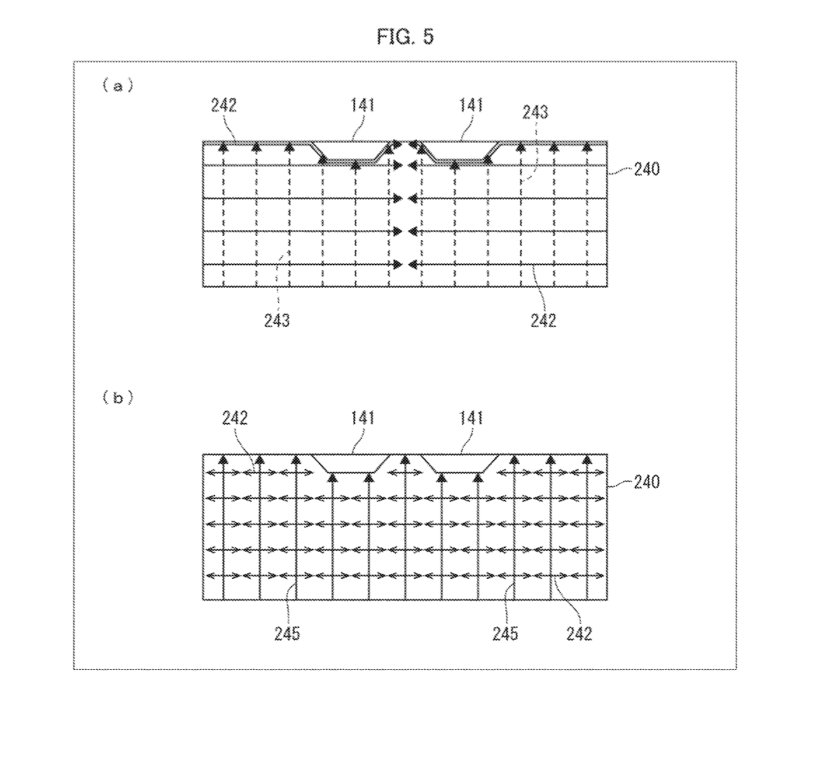

The following description will discuss another embodiment of the present invention. FIG. 4 is a development view of an image capturing device in accordance with Embodiment 2 of the present invention, the view schematically showing how members of the image capturing device are arranged. The present embodiment is identical in configuration to Embodiment 1 except that the present embodiment includes two camera units and two facing portions corresponding to the respective camera units. For convenience of explanation, any member of the present embodiment that is identical in function to a member described for the embodiment above is assigned the same reference sign. Such a member is not described again here.

The image capturing device 200, as illustrated in FIG. 4, includes a backlight 210, two camera units 120, a first polarizing plate 130, a TFT substrate 240, a color filter substrate 250, a second polarizing plate 160, and a cover glass 170. The TFT substrate 240 and the color filter substrate 250 sandwich a liquid crystal layer. Among the above members of the image capturing device 200, the members other than the backlight 210 each have a rectangular planar shape.

The backlight 210 has a rectangular planar shape having two cutouts at a central portion of a long side of the rectangle. The two cutouts are next to each other in the longitudinal direction of the rectangle with the longitudinal center of the rectangle between the two cutouts. The two cutouts each have a planar shape identical to that of the cutout for Embodiment 1 (for example, a trapezoid).

The TFT substrate 240 is configured similarly to the TFT substrate 140 for Embodiment 1 except that the TFT substrate 240 includes two facing portions 141. The color filter substrate 250 is configured similarly to the TFT substrate 140 and color filter substrate 150 for Embodiment 1 except that the color filter substrate 250 includes two facing portions 151. The TFT substrate 240 has two facing portions 141 that are next to each other in the longitudinal direction of the TFT substrate 240 and that coincide with the respective cutouts in the stacking direction. The color filter substrate 250 has two facing portions 151 that are next to each other in the longitudinal direction of the color filter substrate 250 and that coincide with the respective cutouts in the stacking direction.

As illustrated in (a) of FIG. 5, the TFT substrate 240 may, for instance, be provided with (i) two gate drive circuits (not shown) each present along one of the opposite side edges of the TFT substrate 240, (ii) gate lines 242 (indicated with solid lines) extending from each gate drive circuit in the longitudinal direction of the TFT substrate 240 toward the longitudinal center of the TFT substrate 240, and (iii) source lines 243 (indicated with broken lines) extending in the transverse direction of the TFT substrate 240. This configuration involves use of gate lines 242 that bypass the facing portions 141 and that are longer than the other. This may result in the gate drive circuits being larger in size and require the frame 172 of the cover glass 170 to have wider short-side portions.

To ensure a larger image display region, the TFT substrate 240 may, as illustrated in (b) of FIG. 5, alternatively be provided with (i) a plurality of gate drive circuits 245 extending in the transverse direction of the TFT substrate 240 through an area corresponding to the image display region and (ii) gate lines 242 extending from each gate drive circuit 245 in the longitudinal direction of the TFT substrate 240. This configuration allows the individual gate drive circuits 245 to be smaller and the individual gate lines 242 to be shorter. This in turn eliminates the need to use a wider frame 172 for larger gate drive circuits as described above.

### Embodiment 3

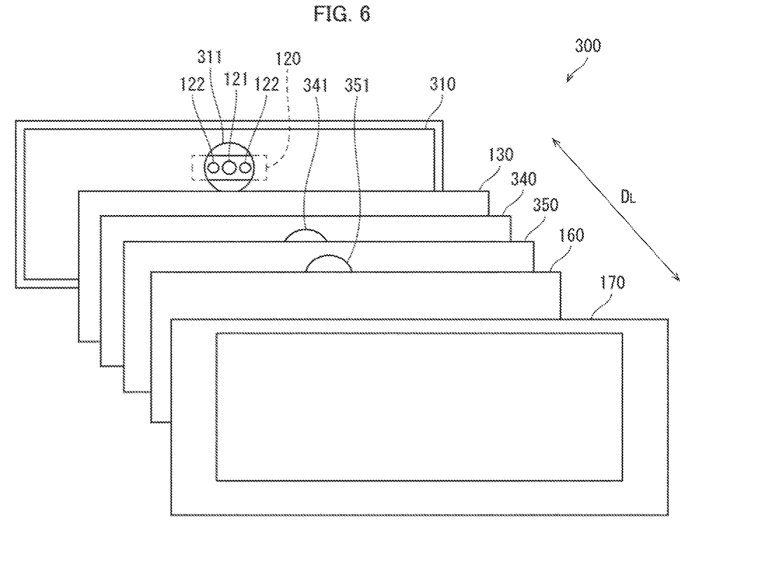

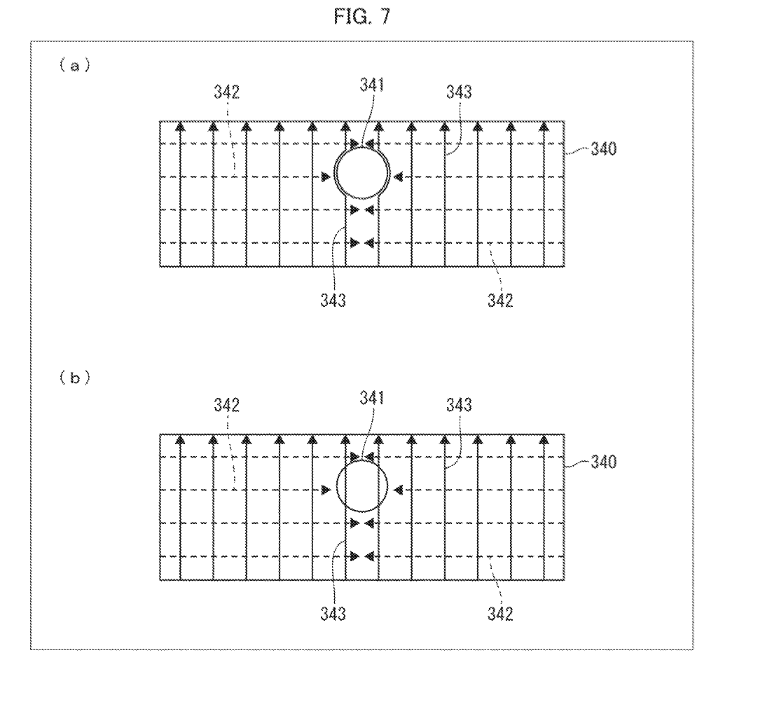

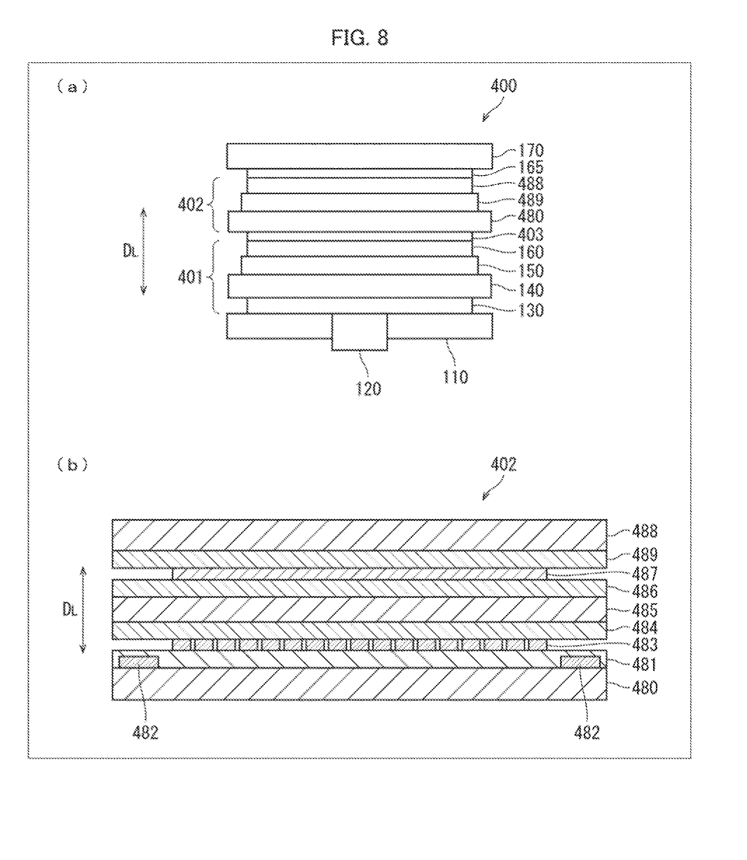

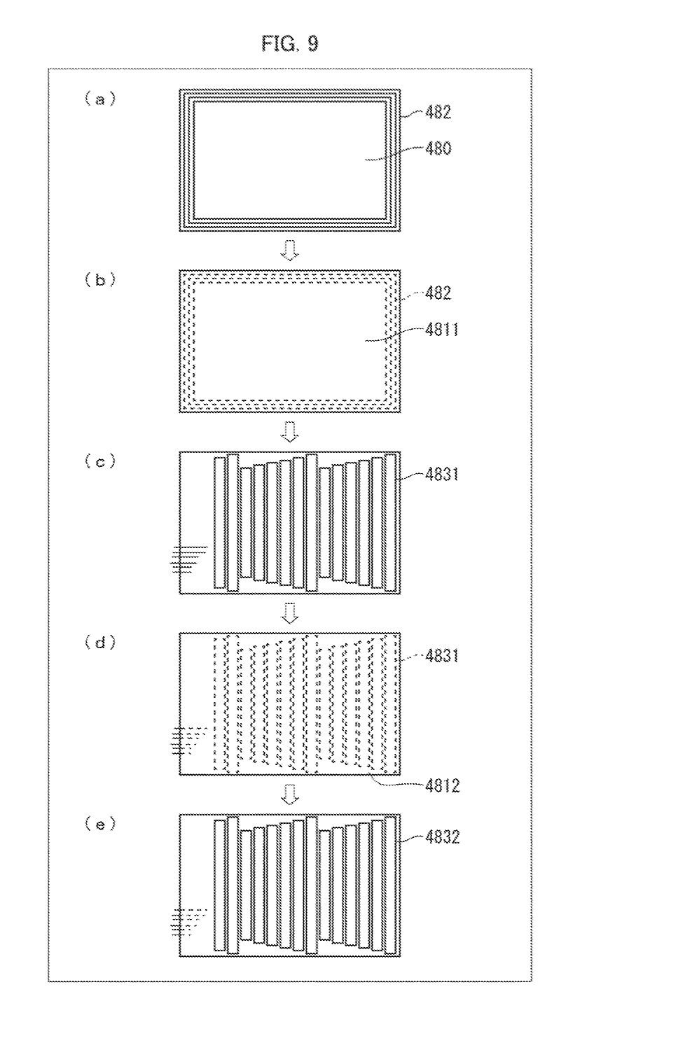

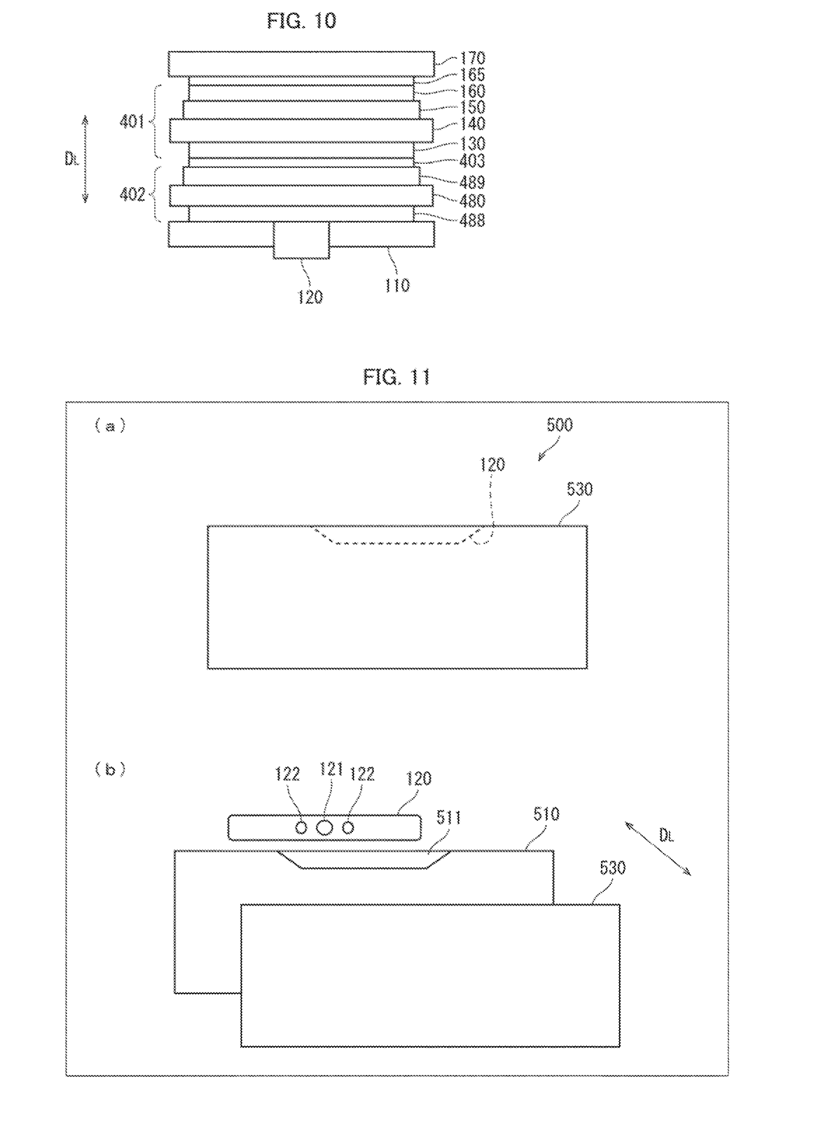

FIG. 6 is a development view of an image capturing device in accordance with Embodiment 3 of the present invention, the view schematically showing how members of the image capturing device are arranged. The present embodiment is identical in configuration to Embodiment 1 except that the present embodiment includes (i) a camera unit positioned closer to the center of the image display region and (ii) facing portions corresponding to the camera unit. For convenience of explanation, any member of the present embodiment that is identical in function to a member described for the embodiments above is assigned the same reference sign. Such a member is not described again here.

The image capturing device 300, as illustrated in FIG. 6, includes a backlight 310, a camera unit 120, a first polarizing plate 130, a TFT substrate 340, a color filter substrate 350, a second polarizing plate 160, and a cover glass 170. The TFT substrate 340 and the color filter substrate 350 sandwich a liquid crystal layer. Among the above members of the image capturing device 300, the members other than the backlight 310 each have a rectangular planar shape.

The backlight 310 has a rectangular planar shape having an opening 311 at a central portion of the rectangle. The opening 311 is inside the image display region. The opening 311 has a circular planar shape, for example. The opening 311 is a cutout made by cutting out a portion of the planar shape of the backlight 310. The camera unit 120 is disposed on the back-surface side of the backlight 310 such that the camera 121 and the IR light sources 122 are inside the opening 311 in a plan view.

The TFT substrate 340 is configured similarly to the TFT substrate 140 for Embodiment 1 except that the TFT substrate 340 includes a facing portion 341. The facing portion 341 is a part of the TFT substrate 340, and has a circular shape as with the opening 311 of the backlight 310 and coincides on the TFT substrate 340 with the opening 311 in the stacking direction. The facing portion 341 is similar to the facing portion 141 also in that any electronic circuit has been removed from the facing portion 341 and that the facing portion 341 is made substantially of a glass substrate alone.

The color filter substrate 350 is configured similarly to the color filter substrate 150 for Embodiment 1 except that the color filter substrate 350 includes a facing portion 351 similarly to the facing portion 341. The facing portion 351 of the color filter substrate 350 has a circular shape as with the opening 311 of the backlight 310 and coincides on the TFT substrate 350 with the opening 311 in the stacking direction. The facing portion 351 is similar to the facing portion 151 also in that any color material has been removed from the facing portion 351 and that the facing portion 351 is made substantially of a glass substrate alone.

The image capturing device 300 has a space between the facing portions 341 and 351 on the side of the above liquid crystal layer, as with the facing portions 141 and 151, which space is filled with a liquid crystal composition as a light-transmitting medium. The facing portions 341 and 351 each have a peripheral edge along which a black matrix is present. The facing portions 341 and 351 are thus each bordered with a black matrix.

As illustrated in (a) of FIG. 7, the TFT substrate 340 may be provided with, for example, (i) gate lines 342 (indicated with broken lines) extending from each longitudinal edge in the longitudinal direction of the TFT substrate 340 toward the longitudinal center of the TFT substrate 340, (ii) a source drive circuit (not shown) provided along a long side of the TFT substrate 340, and (iii) source lines 343 (indicated with solid lines) extending from the source drive circuit in the transverse direction of the TFT substrate 340. This configuration requires a space for a plurality of source lines to pass through around the facing portion 341 so that the plurality of source lines bypass the facing portion 341. This may require the frame to have a wide portion for that portion.

To ensure a larger image display region, the TFT substrate 340 may, as illustrated in (b) of FIG. 7, alternatively be provided with, instead of source lines that bypass the facing portion 341, source lines 343 that are as long as the other source lines and that pass through the facing portion 341. This configuration eliminates the need for source lines to bypass the facing portion 341, and thereby eliminates the need to use a frame 172 having a wide portion around the facing portion 341.

### Embodiment 4

The present embodiment is an image capturing device identical in configuration to Embodiment 1 except that the image capturing device further includes a switch liquid crystal layer for three-dimensional display. (a) of FIG. 8 is a diagram schematically illustrating how members of the image capturing device in accordance with Embodiment 4 of the present invention are stacked. (b) of FIG. 8 is a diagram schematically illustrating how members of the switch liquid crystal layer for the image capturing device are stacked. For convenience of explanation, any member of the present embodiment that is identical in function to a member described for the embodiments above is assigned the same reference sign. Such a member is not described again here.

The image capturing device 400, as illustrated in (a) of FIG. 8, includes a backlight 110, a camera unit 120, a main liquid crystal layer 401, a switch liquid crystal layer 402 present on the display-surface side of the main liquid crystal layer 401, and a cover glass 170. The backlight 110, the camera unit 120, and the main liquid crystal layer 401 are configured similarly to the image capturing device 100 except that none of the backlight 110, the camera unit 120, and the main liquid crystal layer 401 includes a cover glass 170.

The switch liquid crystal layer 402 is bonded to the main liquid crystal layer 401 via an adhesive layer 403 made of, for example, an optically clear resin (OCR) or optical clear adhesive (OCA). The switch liquid crystal layer 402 serves to form a black-and-white striped pattern as a parallax barrier and has, for example, a stack structure for a twisted nematic (TN) liquid crystal. The switch liquid crystal layer 402, as illustrated in (b) of FIG. 8, includes (i) a liquid crystal layer 485, (ii) liquid crystal alignment layers 484 and 486 sandwiching the liquid crystal layer 485, (iii) a substrate (SEG substrate) having a structure corresponding to the segment, and (iv) a substrate (COM substrate) on the side of the common electrode, the liquid crystal layer 485 and the liquid crystal alignment layers 484 and 486 being sandwiched between the SEG substrate and the COM substrate.

The SEG-side substrate includes (i) a SEG substrate 480 made of glass, (ii) lead wires 482 made of metal and extending on a front surface of the SEG substrate 480 along edges thereof, (iii) an insulating layer 481 covering the entire front surface of the SEG substrate 480, and (iv) an ITO electrode 483 present on the insulating layer 481 and having a planar shape corresponding to the above striped pattern. The COM-side substrate includes (i) a polarizing plate 488, (ii) a COM substrate 489 made of glass and present on the polarizing plate 488, and (iii) an ITO electrode 487 present on the COM substrate 489. The ITO electrode 487 has a rectangular planar shape that covers all the striped pattern of the ITO electrode 483 on the SEG-side substrate.

When the switch liquid crystal layer 402 is activated so that the liquid crystal molecules are oriented to have an orientation distribution, the switch liquid crystal layer 402 may act as a lens. The switch liquid crystal layer 402 may consequently influence how light travels toward the camera 121.

In view of the above, the switch liquid crystal layer 402 may include no facing portion as long as the camera 121 can capture a sufficiently clearly image. For instance, that portion of each of the ITO electrodes 483 and 487 of the switch liquid crystal layer 402 which coincides with the facing portions in the stacking direction may have a desired pattern such as the above (for example, a striped pattern) as long as the camera 121 can capture a sufficiently clear image.

Alternatively, that portion of each of the ITO electrodes 483 and 487 which coincides with the facing portions in the stacking direction may have a uniform pattern other than the striped pattern such as a solid pattern. Such an embodiment is preferable as it facilitates infrared light traveling in a straight line through the switch liquid crystal layer 402 and the camera 121 capturing a clearer image.

The switch liquid crystal layer 402 may be prepared by a publicly known method. For instance, the SEG-side substrate may be prepared by, as illustrated in FIG. 9, (a) forming lead wires 482 made of metal on a front surface of the SEG substrate 480 along the edges thereof, (b) forming an insulating layer 4811 on the SEG substrate 480, (c) forming an ITO electrode 4831 in a striped pattern on the insulating layer 4811, (d) forming an insulating layer 4812 on the ITO electrode 4831, and (e) forming an ITO electrode 4832 as an auxiliary electrode having a striped pattern corresponding to the ITO electrode 4831.

FIG. 9 illustrates the ITO electrode 483 on the SEG-side substrate as having a striped pattern having stripes that become gradually longer toward an end of the SEG substrate 480. FIG. 9 schematically illustrates the individual stripes (that is, vertical barrier electrodes) of the ITO electrode 483 as being connected to respective lead wires 482 extending in a direction that crosses the stripes. In the area of such connection, the barrier electrodes may have the same length or respective lengths different from one another.

Activating only the main liquid crystal layer 401 causes the image capturing device 400 to display a two-dimensional image. Further activating the switch liquid crystal layer 402 causes the switch liquid crystal layer 402 to display a black-and-white image in a striped pattern. The image in a striped pattern serves as a parallax barrier, which allows an image formed by the main liquid crystal layer 401 to be displayed three-dimensionally. The switch liquid crystal layer 402 is sufficiently light-transmitting with respect to infrared light. This allows the camera 121 to capture a sufficiently clear image regardless of whether the switch liquid crystal layer 402 is active.

The image capturing device 400 may be configured as illustrated in FIG. 10 such that the main liquid crystal layer 401 and the switch liquid crystal layer 402 are switched around in the stacking direction. In other words, the switch liquid crystal layer 402 may be adjacent to the backlight 110 and the camera unit 120 on the display-surface side. With this configuration, the polarizing plate 488 of the switch liquid crystal layer 402 is between the backlight 110 and the SEG substrate 480, and the COM substrate 489 of the switch liquid crystal layer 402 is bonded to the first polarizing plate 130 of the main liquid crystal layer 401 via the adhesive layer 403.

### Embodiment 5

The present embodiment is an image capturing device similar in configuration to Embodiment 1 except that the image capturing device includes an organic light-emitting diode (OLED) layer as an image forming layer. (a) of FIG. 11 is a schematic front view of the image capturing device in accordance with Embodiment 5 of the present invention. (b) of FIG. 11 is a development view of the image capturing device, the view schematically showing how members of the image capturing device are arranged. For convenience of explanation, any member of the present embodiment that is identical in function to a member described for the embodiments above is assigned the same reference sign. Such a member is not described again here.

The image capturing device 500, as illustrated in (a) and (b) of FIG. 11, includes an OLED panel 510, a camera unit 120, and a polarizing plate 530 present on the display-surface side of the OLED panel 510.

The OLED panel 510 has a rectangular planar shape having a cutout at a central portion of a long side of the rectangle. The cutout has a trapezoidal planar shape similarly to that of the cutout for Embodiment 1. The camera unit 120 is oriented so as to have a camera 121 and IR light sources 122 facing the display-surface side. The polarizing plate 530 serves to reduce reflection inside the panel, and has a rectangular planar shape that covers the OLED panel 510 and the cutout.

The image capturing device 500 displays a clear image formed by the OLED panel 510. Since (i) the image capturing device 500 includes the above cutout, and (ii) infrared light passes through the polarizing plate 530 at a sufficiently high transmittance, the camera 121 can capture a clear image. The polarizing plate 530 prevents the camera 121 from being easily visible from the display-surface side. The image capturing device 500 thus has an attractive appearance.

### Variations

The image capturing device in accordance with any of the embodiments above may, as long as the image capturing device produces its effects, include a member in addition to the members described above or a member further in place of any of the members described above.

For instance, while the facing portions are filled with a liquid crystal composition as a light-transmitting medium, this light-transmitting medium may be other than a liquid crystal composition. The light-transmitting medium may be any appropriate material that causes substantially no birefringence of infrared light. The light-transmitting medium is preferably the liquid crystal composition for the liquid crystal layer because such a configuration makes it possible to fill the facing portions with the liquid crystal composition at the same time as dropping or injecting the liquid crystal composition to prepare a liquid crystal layer.

In a case where the light-transmitting medium is not the liquid crystal composition, the image capturing device further includes a sealing section for hermetically sealing the facing portions in a fluid-tight manner with respect to the remaining portion to prevent the liquid crystal composition of the liquid crystal layer and the light-transmitting medium from being mixed with each other in the image capturing device.

Examples of the light-transmitting medium other than the liquid crystal composition include silicone resin. The sealing section is made of a material such as epoxy resin and acrylic resin for use in normal liquid crystal panels.

The sealing section may contain a black matrix. With this configuration, the sealing section not only hermetically seals the facing portions, but also improves the light-blocking property of the portion other than the facing portions. The facing portions hermetically sealed by the sealing section may be filled with, as a light-transmitting medium, the liquid crystal composition of which the liquid crystal layer is made.

The embodiments above are configured such that the IR light sources 122 are in the vicinity of the camera 121. The IR light sources 122 may, however, each be provided at any position in the image display region as long as the IR light sources 122 can irradiate an object for the camera 121 with infrared light sufficiently. The IR light sources may, for instance, each be provided at a position away from the camera on the planar shape of the backlight so as to be independent of the camera. The facing portions may each include (i) a facing portion for the camera and (ii) a facing portion for the IR light sources independent of the camera.

The image forming layer may include a constituent element of an image display device other than a liquid crystal display device and an OLED panel as long as the image forming layer includes the facing portions and polarizing plate(s) described above. Examples of the image display device include a quantum-dot light-emitting diode (QLED) panel and a micro LED panel.

The embodiments above may each be configured such that the facing portions each contain an electronic circuit and/or color material as long as the camera can capture a sufficiently clear image. The facing portions may, for instance, each contain an electronic circuit and/or color material as long as (i) infrared light has a transmittance of not less than 70% at the facing portions, (ii) infrared light has a transmittance of not less than 85% at the image forming layer, or (iii) no electronic circuit or color material is present on the respective optical paths of the camera and IR light sources. Infrared light preferably has as high a transmittance as possible at the facing portions because a higher transmittance allows the IR light sources to consume less electric power.

The facing portions may each be formed by removing an electronic circuit or color material on an existing TFT substrate or color filter substrate by rubbing the surface or by dissolving the electronic circuit or color material with use of acid or solvent.

The embodiments above each include a VA display device as a liquid crystal display device. The liquid crystal display device may, however, be other than a VA display device. The liquid crystal display device may, for example, be a TN display device or an in-plane switching (IPS) display device.

The liquid crystal display device in accordance with any of the embodiments above includes a first transparent electrode and a second transparent electrode as described above. Those transparent electrodes of the liquid crystal display device may be positioned as appropriate depending on the type of liquid crystal display device. For instance, a VA or TN display device may include both the first and second transparent electrode, whereas an IPS display device may include only the first transparent electrode (which is on the TFT substrate).

[Recap]

An image capturing device in accordance with an embodiment of the present invention includes: an image forming layer for forming an image in an image display region; a polarizing plate provided inside the image forming layer or on a display-surface side of the image forming layer; a camera provided on a back-surface side of the image forming layer and facing the display-surface side of the image forming layer; and a light source provided on the back-surface side of the image forming layer and facing the display-surface side of the image forming layer so as to emit infrared light toward the display-surface side, the image forming layer having a facing portion facing the camera and the light source from which facing portion an electronic circuit, a colored portion, and a black matrix have been removed partially or entirely.

With the above configuration, the camera and the light source, which are placed inside the image display region of the image forming layer, cause substantially no influence on the appearance of the image forming layer. The image capturing device may be produced with use of main components for an image display device including no camera or light source such as the above. The image capturing device, which includes a display, has an appearance influenced less by the display and can be produced at a lower cost.

More specifically, the image capturing device in accordance with an embodiment may be configured such that the image forming layer includes a stack of: a backlight; a first polarizing plate; at least one transparent electrode; a thin film transistor substrate; a liquid crystal layer; a color filter substrate; a second polarizing plate oriented so as to meet a crossed Nicol relation with the first polarizing plate; and a cover glass, the backlight has a planar shape having a cutout, the camera and the light source are positioned at the cutout, the electronic circuit has been removed partially or entirely from the facing portion of the thin film transistor substrate, and the colored portion and the black matrix have been removed partially or entirely from the facing portion of the color filter substrate.

With the above configuration, the image capturing device may include a publicly known liquid crystal display device as the image forming layer and the polarizing plate.

The image capturing device in accordance with an embodiment may be configured such that the facing portion of the color filter substrate is bordered with a black matrix. This configuration is more effective as it increases the light-blocking property of the facing portion of the color filter section and reduces the influence of the facing portion on an image displayed in the image display region.

The image capturing device in accordance with an embodiment may be configured such that the liquid crystal layer is a layer of a twisted nematic liquid crystal or of a vertical alignment liquid crystal, and the at least one transparent electrode includes (i) a first transparent electrode in contact with the thin film transistor substrate on the display-surface side of the thin film transistor substrate and (ii) a second transparent electrode in contact with the color filter substrate on the back-surface side of the color filter substrate. This configuration is more effective as it reduces deficiencies in alignment of the liquid crystal of the liquid crystal layer and reduces the influence of the facing portion on an image displayed in the image display region.

The image capturing device in accordance with an embodiment may alternatively further include: a sealing section for isolating the facing portion of the image forming layer from a remaining portion of the image forming layer in a fluid-tight manner; and a light-transmitting medium with which the facing portion isolated by the sealing section is filled which light-transmitting medium is other than a liquid crystal composition of which the liquid crystal layer is made. This configuration is also more effective as it reduces deficiencies in alignment of the liquid crystal of the liquid crystal layer and reduces the influence of the facing portion on an image displayed in the image display region.

The image capturing device in accordance with an embodiment may be configured such that the thin film transistor substrate includes a gate drive circuit inside the image display region. This configuration is preferable as it allows the frame to have a small width in the vicinity of the facing portion. The above configuration is thus more effective as it allows the image display region to be larger.

The image capturing device in accordance with an embodiment may further include a switch liquid crystal layer coinciding with the image forming layer. This configuration allows the image capturing device to display an image not only two-dimensionally but also three-dimensionally in the image display region.

The image capturing device in accordance with an embodiment may be configured such that the image forming layer is a layer of an organic light-emitting diode. This means that the image capturing device may include, other than a liquid crystal display device, a publicly known image display device including an image forming layer and a polarizing plate.

The image capturing device in accordance with an embodiment may be configured such that the electronic circuit includes either or both of a switching element and wiring. This configuration is more effective as removing those switching element and wiring from the facing portion increases the transmittance of infrared light at the facing portion.

The image capturing device includes a display device and is capable of capturing an image of an object on the display-surface side of the display device. The image capturing device is thus suitably usable in capturing an image of the viewer of the display screen. The image capturing device is suitably usable in, for example, a DMS including (i) a display device for displaying information about driving of the automobile and (ii) an image capturing device for monitoring the state of the driver.

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

### REFERENCE SIGNS LIST

100, 200, 300, 400, 500 Image capturing device
110 Backlight
120 Camera unit
121 Camera
122 IR light source
130 First polarizing plate
140, 240, 340 Thin film transistor (TFT) substrate
141, 151, 341, 351, 511 Facing portion
142 Light-transmitting medium
143 Black matrix
150, 250, 350 Color filter substrate
160 Second polarizing plate
165 Adhesive sheet
170 Cover glass
171 Glass plate
172 Frame
242, 342 Gate line
243, 343 Source line
245 Gate drive circuit
311 Opening
401 Main liquid crystal layer
402 Switch liquid crystal layer
403 Adhesive layer
480 SEG substrate
481, 4811, 4812 Insulating layer
482 Lead wire
483, 487, 4831, 4832 ITO electrode
484, 486 Liquid crystal alignment layer
485 Liquid crystal layer
488, 530 Polarizing plate
489 COM substrate
510 OLED panel
D_{L} Arrow indicative of a stacking direction

1. An image capturing device, comprising:
an image forming layer for forming an image in an image display region;
a polarizing plate provided inside the image forming layer or on a display-surface side of the image forming layer;
a camera provided on a back-surface side of the image forming layer and facing the display-surface side of the image forming layer; and
a light source provided on the back-surface side of the image forming layer and facing the display-surface side of the image forming layer so as to emit infrared light toward the display-surface side,
the image forming layer having a facing portion facing the camera and the light source from which facing portion an electronic circuit, a colored portion, and a black matrix have been removed partially or entirely.

2. The image capturing device according to claim 1, wherein
the image forming layer includes a stack of:
a backlight;
a first polarizing plate;
at least one transparent electrode;
a thin film transistor substrate;
a liquid crystal layer;
a color filter substrate;
a second polarizing plate oriented so as to meet a crossed Nicol relation with the first polarizing plate; and
a cover glass,
the backlight has a planar shape having a cutout,
the camera and the light source are positioned at the cutout,
the electronic circuit has been removed partially or entirely from the facing portion of the thin film transistor substrate, and
the colored portion and the black matrix have been removed partially or entirely from the facing portion of the color filter substrate.

3. The image capturing device according to claim 2, wherein
the facing portion of the color filter substrate is bordered with a black matrix.

4. The image capturing device according to claim 3, wherein
the liquid crystal layer is a layer of a twisted nematic liquid crystal or of a vertical alignment liquid crystal, and
the at least one transparent electrode includes (i) a first transparent electrode in contact with the thin film transistor substrate on the display-surface side of the thin film transistor substrate and (ii) a second transparent electrode in contact with the color filter substrate on the back-surface side of the color filter substrate.

5. The image capturing device according to claim 2, further comprising:
a sealing section for isolating the facing portion of the image forming layer from a remaining portion of the image forming layer in a fluid-tight manner; and
a light-transmitting medium with which the facing portion isolated by the sealing section is filled which light-transmitting medium is other than a liquid crystal composition of which the liquid crystal layer is made.

6. The image capturing device according to claim 2, wherein
the thin film transistor substrate includes a gate drive circuit inside the image display region.

7. The image capturing device according to claim 2, further comprising:
a switch liquid crystal layer coinciding with the image forming layer.

8. The image capturing device according to claim 1, wherein
the image forming layer is a layer of an organic light-emitting diode.

9. The image capturing device according to claim 1, wherein
the electronic circuit includes either or both of a switching element and wiring.
